(19) United States
(12) Patent Application Publication
(10) Pub. No.: US 2007/0188208 A1
(43) Pub. Date: Aug. 16, 2007

(54) Semiconductor integrated circuit

(75) Inventor: Kinya Mitsumoto, Tamamura (JP)

Correspondence Address: Stanley P. Fisher;Reed Smith Hazel & Thomas LLP, Suite 1400, 3110 Fairview Park Drive, Falls Church, VA, 22042-4503, US

(73) Assignee: Renesas Technology Corp.

(21) Appl. No.: 11/783,382

(22) Filed: Apr. 9, 2007

Related U.S. Application Data
(62) Division of application No. 10/983,722, filed on Nov. 9, 2004.

(30) Foreign Application Priority Data
Nov. 14, 2003 (JP) 2003-385744

(51) Int. Cl. H03K 3/356

(52) U.S. Cl. 327/212

(57) ABSTRACT

In a semiconductor integrated circuit including first and second circuits whose inputs/outputs are in cross-connection, an output node of the first circuit is driven on the basis of a first input signal, and an output node of the second circuit is driven on the basis of a second input signal. At this time, there are provided a first driving transistor capable of driving the output node of the first circuit on the basis of the second input signal, and a second driving transistor capable of driving the output node of the second circuit on the basis of the first input signal. The output nodes are driven using the first and second driving transistors, respectively.

### CROSS REFERENCE TO RELATED APPLICATIONS

This application is a Divisional application of U.S. application Ser. No. 10/983,722 filed Nov. 9, 2004. Priority is claimed based on U.S. application Ser. No. 10/983,722 filed Nov. 9, 2004, which claims the priority date of Japanese Patent Application No. 2003-385744 filed Nov. 14, 2003.

### BACKGROUND OF THE INVENTION

The present invention relates to a semiconductor integrated circuit, and more particularly to a technology for reducing a difference between the rising delay time and the falling delay time of an output signal in a logic circuit included in the semiconductor integrated circuit. More concretely, it relates to the technology which is effective when applied to, e.g., a flip-flop circuit and a latch circuit.

A master-slave latch circuit, which is classified as an example of logic circuits, is configured by cascade-connecting a master latch and a slave latch. Here, there has been known the following technology: An additional circuit with a pull-up or pull-down function is connected to one input terminal of this master latch or slave latch. This is performed so as to automatically determine the output signal at the time of switching on power-supply. As regards this technology, refer to, e.g., FIG. 1 of JP-A-06-140885.

Also, there has been known the following technology: In order to swiftly escape from a quasi-stable state of the flip-flop circuit, a capacitor is interposed between an input line and an output line. Then, electrostatic energy of this capacitor is consumed and used such that influence by voltage on the input line will be exerted on the output line as voltage change in the same direction. As regards this technology, refer to, e.g., FIG. 1 of JP-A-11-340957.

### SUMMARY OF THE INVENTION

In general, a RS flip-flop circuit, which is classified as an example of the logic circuits, is formed using NAND gates or NOR gates. In particular, in the case of forming the RS flip-flop circuit using the NOR gates, the present application's inventor has found out that differences exist between the rising times and the falling times of output signals acquired from a non-inverted output terminal and an inverted output terminal. Namely, when a set input terminal or a reset input terminal is transitioned from a low level to a high level, the inverted output terminal or the non-inverted output terminal is swiftly transitioned from a high level to a low one. In contrast thereto, a certain amount of time becomes required for the transition from the low level to the high level at the output terminal. This is attributed to a situation that the cross-connection between input terminals and output terminals of the circuit.

When, e.g., the non-inverted output terminal is transitioned from the high level to the low one, the inverted output terminal turns into high level in response to the state of the low level at the non-inverted output terminal. Accordingly, the transition time from the low level to the high one at the inverted output terminal becomes longer than the transition time from the high level to the low one at the non-inverted output terminal. For basically the same reason, the transition time from the low level to the high one at the non-inverted output terminal becomes longer than the transition time from the high level to the low one at the inverted output terminal. This means that a timing with which one of the output signals at a complementary level in the RS flip-flop circuit cuts across a logical threshold-value when the one of the output signals has been transitioned from the high level to the low one differs from a timing with which the other of the output signals at the complementary level cuts across the logical threshold-value when the other has been transitioned from the low level to the high one. As a consequence, in a circuit located at the subsequent stage of the RS flip-flop circuit, it becomes necessary to take up an enlarged timing margin for taking in the input signals. On account of this, a certain amount of time becomes required for signal transmission from the RS flip-flop circuit to the subsequent-stage circuit.

It is an object of the present invention to provide a technology for reducing differences between the rising times and the falling times of output signals.

The foregoing and the other objects of the present invention and novel characteristics thereof will become apparent from the description and accompanying drawings of the present specification.

Hereinafter, the brief explanation will be given below concerning the outline of representative inventions to be disclosed in the present application.

Namely, in a semiconductor integrated circuit including a first circuit, and a second circuit whose input/output is cross-connected to the first circuit, an output node of the first circuit being driven on the basis of a first input signal, an output node of the second circuit being driven on the basis of a second input signal, there are provided a first driving transistor capable of driving the output node of the first circuit on the basis of the second input signal, and a second driving transistor capable of driving the output node of the second circuit on the basis of the first input signal.

According to the above-described integrated circuit, the first driving transistor drives the output node of the first circuit to a high level on the basis of the second input signal, and the second driving transistor drives the output node of the second circuit to a high level on the basis of the first input signal. This driving makes the falling time of the inverted output terminal and the rising time of the non-inverted output terminal substantially equal to each other, and also makes the rising time of the inverted output terminal and the falling time of the non-inverted output terminal substantially equal to each other. This condition reduces differences between the rising times and the falling times of output signals. Accordingly, the timing with which one of the output signals at a complementary level cuts across a logical threshold-value when the one of the output signals has been transitioned from the high level to the low one becomes substantially equal to the timing with which the other of the output signals at the complementary level cuts across the logical threshold-value when the other has been transitioned from the low level to the high one. As a result, in the subsequent-stage circuit, it becomes possible to reduce the timing margin for taking in the input signals. Consequently, by the amount equivalent thereto, it becomes possible to implement shortening of the signal-transmission time.

In a semiconductor integrated circuit including a latch circuit capable of latching input data in synchronization with a clock signal, the latch circuit includes a first circuit formed by a connection of a first-conductivity-type first transistor and a second-conductivity-type second transistor whose conductivity type differs from that of the first transistor, a second circuit formed by a connection of a first-conductivity-type third transistor and a second-conductivity-type fourth transistor, a second-conductivity-type fifth transistor capable of driving an output node of the first circuit to a low level in response to a first input signal and the clock signal, a second-conductivity-type sixth transistor capable of driving an output node of the second circuit to a low level in response to a second input signal and the clock signal, a first-conductivity-type seventh transistor capable of driving the output node of the first circuit to a high level, a third circuit capable of driving the seventh transistor on the basis of the second input signal and the clock signal, a first-conductivity-type eighth transistor capable of driving the output node of the second circuit to a high level, and a fourth circuit capable of driving the eighth transistor on the basis of the first input signal and the clock signal.

In the above-described configuration, the seventh transistor drives the output node of the first circuit to the high level on the basis of the second input signal and the clock signal, and the eighth transistor drives the output node of the second circuit to the high level on the basis of the first input signal and the clock signal. The driving like this makes the falling time of the inverted output terminal and the rising time of the non-inverted output terminal substantially equal to each other, and also makes the rising time of the inverted output terminal and the falling time of the non-inverted output terminal substantially equal to each other. This condition reduces differences between the rising times and the falling times of output signals.

In a master-slave latch circuit as well which includes a master latch circuit and a slave latch circuit connected to the master latch circuit, held data held in the master latch circuit being transmitted to the slave latch circuit in synchronization with a clock signal inputted, the slave latch circuit includes a first circuit formed by a connection of a first-conductivity-type first transistor and a second-conductivity-type second transistor whose conductivity type differs from that of the first transistor, a second circuit formed by a connection of a first-conductivity-type third transistor and a second-conductivity-type fourth transistor, a second-conductivity-type fifth transistor capable of driving an output node of the first circuit to a low level in response to a first input signal and the clock signal, a second-conductivity-type sixth transistor capable of driving an output node of the second circuit to a low level in response to a second input signal and the clock signal, a first-conductivity-type seventh transistor capable of driving the output node of the first circuit to a high level, a third circuit capable of driving the seventh transistor on the basis of the second input signal and the clock signal, a first-conductivity-type eighth transistor capable of driving the output node of the second circuit to a high level, and a fourth circuit capable of driving the eighth transistor on the basis of the first input signal and the clock signal, wherein, when the first circuit and the second circuit are cross-connected to each other, the falling time of the inverted output terminal and the rising time of the non-inverted output terminal are made substantially equal to each other, and also the rising time of the inverted output terminal and the falling time of the non-inverted output terminal are made substantially equal to each other. This condition reduces differences between the rising times and the falling times of output signals.

In a semiconductor integrated circuit including a first circuit formed by a connection of a first-conductivity-type first transistor and a second-conductivity-type second transistor whose conductivity type differs from that of the first transistor, a second circuit formed by a connection of a first-conductivity-type third transistor and a second-conductivity-type fourth transistor, a second-conductivity-type fifth transistor capable of driving an output node of the first circuit to a low level in response to a first input signal, and a second-conductivity-type sixth transistor capable of driving an output node of the second circuit to a low level in response to a second input signal, and wherein the first circuit and the second circuit are cross-connected to each other, wherein a first resistor part is provided between the first transistor and the second transistor, and an inverted output terminal is drawn out of a connection node between the first transistor and the first resistor part. Moreover, a second resistor part is provided between the third transistor and the fourth transistor, and a non-inverted output terminal is drawn out of a connection node between the third transistor and the second resistor part.

When the non-inverted output terminal has been transitioned from the high level to the low one, the inverted output terminal undergoes the low level of the non-inverted output terminal, thereby being driven to the high level. Accordingly, the time during which the inverted output terminal has been transitioned from the low level to the high one becomes longer as compared with the time during which the non-inverted output terminal has been transitioned from the high level to the low one. For basically the same reason, the time during which the non-inverted output terminal has been transitioned from the low level to the high one becomes longer as compared with the time during which the inverted output terminal has been transitioned from the high level to the low one. Then, a pull out of charge from the inverted output terminal is performed via the first resistor part, and a charge pull out from the non-inverted output terminal is performed via the second resistor part. As compared with the case where there exists none of the first resistor part and the second resistor part, the charge pull out like this can be performed at a higher speed by a cross-connection terminal unit, and at a somewhat lower speed by an output terminal unit. This condition allows the implementation of reductions in differences between the rising times and the falling times of output signals.

In a semiconductor integrated circuit including a latch circuit capable of latching input data in synchronization with a clock signal, the latch circuit includes a first circuit formed by a connection of a first-conductivity-type first transistor and a second-conductivity-type second transistor whose conductivity type differs from that of the first transistor, a second circuit formed by a connection of a first-conductivity-type third transistor and a second-conductivity-type fourth transistor, a second-conductivity-type fifth transistor capable of driving an output node of the first circuit to a low level in response to a first input signal, and a second-conductivity-type sixth transistor capable of driving an output node of the second circuit to a low level in response to a second input signal, and wherein the first circuit and the second circuit are cross-connected to each other, wherein a first resistor part is provided between the first transistor and the second transistor, and an inverted output terminal is drawn out of a connection node between the first transistor and the first resistor part. Moreover, a second resistor part is provided between the third transistor and the fourth transistor, and a non-inverted output terminal is drawn out of a connection node between the third transistor and the second resistor part. According to the configuration like this, a charge pull out from the inverted output terminal is performed via the first resistor part, and a charge pull out from the non-inverted output terminal is performed via the second resistor part. As compared with the case where there exists none of the first resistor part and the second resistor part, the charge pull out like this can be performed at a higher speed by a cross-connection terminal unit, and at a somewhat lower speed by an output terminal unit. This condition, as described above, allows the implementation of reductions in differences between the rising times and the falling times of output signals.

In a master-slave-type flip-flop circuit which includes a master latch circuit and a slave latch circuit connected to the master latch circuit, held data held in the master latch circuit being transmitted to the slave latch circuit in synchronization with a clock signal inputted, the slave latch circuit includes a first circuit formed by a connection of a first-conductivity-type first transistor and a second-conductivity-type second transistor whose conductivity type differs from that of the first transistor, a second circuit formed by a connection of a first-conductivity-type third transistor and a second-conductivity-type fourth transistor, a second-conductivity-type fifth transistor capable of driving an output node of the first circuit to a low level in response to a first input signal and the clock signal, and a second-conductivity-type sixth transistor capable of driving an output node of the second circuit to a low level in response to a second input signal and the clock signal, and wherein the first circuit and the second circuit are cross-connected to each other, wherein a first resistor part is provided between the first transistor and the second transistor, and an inverted output terminal is drawn out of a connection node between the first transistor and the first resistor part. Moreover, a second resistor part is provided between the third transistor and the fourth transistor, and a non-inverted output terminal is drawn out of a connection node between the third transistor and the second resistor part. In the configuration like this as well, a charge pull out from the inverted output terminal is performed via the first resistor part, and a charge pull out from the non-inverted output terminal is performed via the second resistor part. As compared with the case where there exists none of the first resistor part and the second resistor part, the charge pull out can be performed at a higher speed by a cross-connection terminal unit, and at a somewhat lower speed by an output terminal unit. This condition, as described above, allows the implementation of reductions in differences between the rising times and the falling times of output signals.

As more concrete modes, each of the first resistor part and the second resistor part can be formed using MOS transistors and resistor elements.

Hereinafter, the brief explanation will be given below concerning an advantage and effect made available by the representative inventions to be disclosed in the present application.

Namely, it becomes possible to reduce differences between the rising times and the falling times of output signals.

Other objects, features and advantages of the invention will become apparent from the following description of the embodiments of the invention taken in conjunction with the accompanying drawings.

### BRIEF DESCRIPTION OF THE DRAWINGS

FIG. 1 is a configuration-embodiment circuit diagram for the main part of a semiconductor integrated circuit according to the present invention;

FIG. 2 is an operation timing diagram for the main part in the circuit illustrated in FIG. 1;

FIG. 3 is a configuration-embodiment circuit diagram for a circuit employed as a comparison target for the circuit illustrated in FIG. 1;

FIG. 4 is an operation timing diagram for the main part in the circuit illustrated in FIG. 3;

FIG. 5 is another configuration-embodiment circuit diagram for the main circuit illustrated in FIG. 1;

FIG. 6 is an operation timing diagram for the main part in the circuit illustrated in FIG. 5;

FIG. 7 is another configuration-embodiment circuit diagram for the main part of the above-described semiconductor integrated circuit;

FIG. 8 is another configuration-embodiment circuit diagram for the main part of the above-described semiconductor integrated circuit;

FIG. 9 is another configuration-embodiment circuit diagram for the main part of the above-described semiconductor integrated circuit;

FIG. 10 is another configuration-embodiment circuit diagram for the main part of the above-described semiconductor integrated circuit;

FIG. 11 is another configuration-embodiment circuit diagram for the main part of the above-described semiconductor integrated circuit;

FIG. 12 is a circuit diagram in which the circuit illustrated in FIG. 11 is represented using logical symbols;

FIG. 13 is another configuration-embodiment circuit diagram for the main part of the above-described semiconductor integrated circuit; and

FIG. 14 is a configuration-embodiment block diagram for a SRAM which is an application embodiment of the circuits illustrated in FIG. 9 and FIG. 10.

### DESCRIPTION OF THE EMBODIMENTS

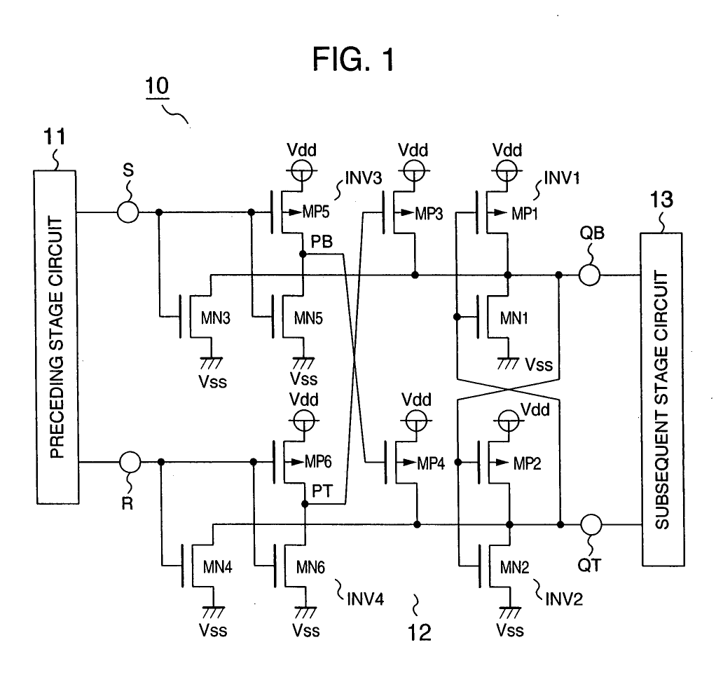

FIG. 1 illustrates the main part of a semiconductor integrated circuit according to the present invention. As illustrated in FIG. 1, this semiconductor integrated circuit 10 includes a RS flip-flop circuit 12, a preceding-stage circuit 11 located at the previous stage of this RS flip-flop circuit 12, and a subsequent-stage circuit 13 located at the subsequent stage of this RS flip-flop circuit 12. Based on the publicly-known semiconductor-integrated-circuit fabrication technologies, the semiconductor integrated circuit 10 is formed on one semiconductor board such as a single-crystal substrate board.

The preceding-stage circuit 11 outputs a set signal and a reset signal. The RS flip-flop circuit 12 includes a set-signal input terminal S, a reset-signal input terminal R, an inverted output terminal QB, and a non-inverted output terminal QT. The RS flip-flop circuit 12 is set by the set signal transmitted from the preceding-stage circuit 11 via the set-signal input terminal S, and is reset by the reset signal transmitted from the preceding-stage circuit 11 via the reset-signal input terminal R. The subsequent-stage circuit 13 takes in output signals at a complementary level, thereby performing predetermined logical operations. Here, the complementary-level output signals are transmitted via the inverted output terminal QB and the non-inverted output terminal QT of the RS flip-flop circuit 12.

The above-described RS flip-flop circuit 12 is configured as follows:

A p-channel MOS transistor MP1 and an n-channel MOS transistor MN1 are connected to each other in series, which forms an inverter INV1. A p-channel MOS transistor MP2 and an n-channel MOS transistor MN2 are connected to each other in series, which forms an inverter INV2. The inverter INV1 and the inverter INV2 are cross-connected to each other. Namely, an output terminal of the inverter INV1 and an input terminal of the inverter INV2 are connected to each other, and an output terminal of the inverter INV2 and an input terminal of the inverter INV1 are connected to each other. An n-channel MOS transistor MN3 is connected to the n-channel MOS transistor MN1 in parallel. This n-channel MOS transistor MN3 is driven by the set signal transmitted via the set-signal input terminal S. An n-channel MOS transistor MN4 is connected to the n-channel MOS transistor MN2 in parallel. This n-channel MOS transistor MN4 is driven by the reset signal transmitted via the reset-signal input terminal R.

Furthermore, in order to reduce differences between the rising times and the falling times of the output signals transmitted from the RS flip-flop circuit 12, there are provided a p-channel MOS transistor MP3 capable of driving the output node (i.e., QB) of the inverter INV1 to a high level, a p-channel MOS transistor MP4 capable of driving the output node (i.e., QT) of the inverter INV2 to a high level, an inverter INV3 capable of driving the p-channel MOS transistor MP4 on the basis of the set signal inputted via the set-signal input terminal S, and an inverter INV4 capable of driving the p-channel MOS transistor MP3 in response to the reset signal inputted via the reset-signal input terminal R. The inverter INV3 is formed by connecting in series a p-channel MOS transistor MP5 and an n-channel MOS transistor MN5. Simultaneously, a source electrode of the p-channel MOS transistor MP5 is connected to a high potential power supply Vdd, and a source electrode of the n-channel MOS transistor MN5 is connected to a low potential power supply Vss. Also, the inverter INV4 is formed by connecting in series a p-channel MOS transistor MP6 and an n-channel MOS transistor MN6. Simultaneously, a source electrode of the p-channel MOS transistor MP6 is connected to a high potential power-supply Vdd, and a source electrode of the n-channel MOS transistor MN6 is connected to a low potential power-supply Vss.

The basic operation of the RS flip-flop circuit 12 is as follows:

Usually, the set-signal input terminal S and the reset-signal input terminal R are maintained at a low level. If, in this state, the set-signal input terminal S is turn into a high level, the n-channel MOS transistor MN3 is turned on, so that the inverted output terminal QB is turned into a low level. Then, in response to the state of the low level of the terminal QB, the non-inverted output terminal QT is turned into a high level. After the logical levels of the terminals QB and QT was established, the set-signal input terminal S is turned into the low level.

Meanwhile, if the reset-signal input terminal R is turned into a high level, the n-channel MOS transistor MN4 is turned on, so that drives the non-inverted output terminal QT is turned into a low level. Then, in response to the state of the low level of the terminal QT, the inverted output terminal QB is turned into a high level. After the logical levels of the terminals QB and QT was established, the reset-signal input terminal R is turned into the low level. The high-level time-period (pw) of the set signal or the reset signal is set as being rather longer than the transition time-period during which the logical levels of the inverted output terminal QB or the non-inverted output terminal QT is established.

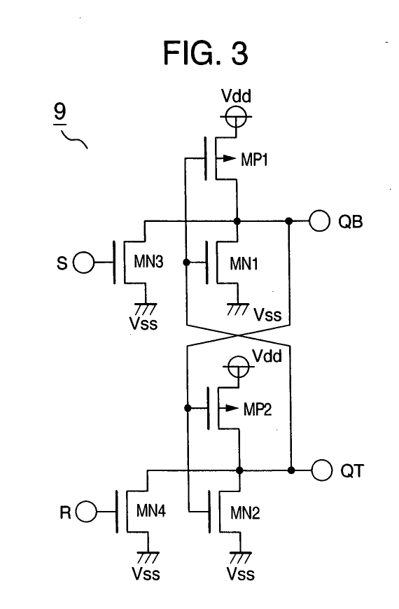

FIG. 3 illustrates another RS flip-flop circuit which is employed as a comparison target for the RS flip-flop circuit 12 illustrated in FIG. 1. The RS flip-flop circuit 9 illustrated in FIG. 3 is equivalent to a circuit resulting from omitting the p-channel MOS transistors MP3 and MP4 and the inverters INV3 and INV4 in the RS flip-flop circuit 12 illustrated in FIG. 1.

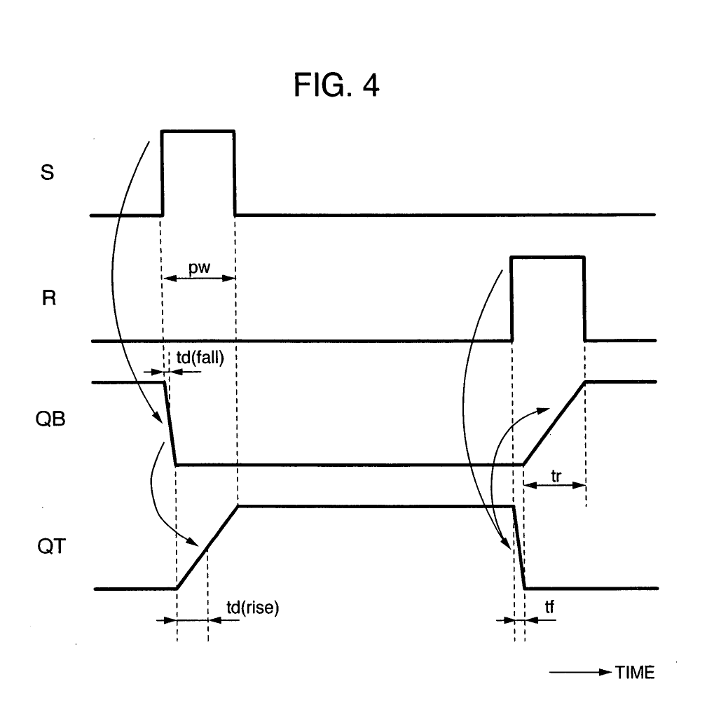

FIG. 4 illustrates an operation timing for the main part in the RS flip-flop circuit 9 illustrated in FIG. 3.

In the RS flip-flop circuit 9, when the non-inverted output terminal QT is transitioned from the high level to the low one, the inverted output terminal QB turns into the high level in response to the state of the low level of the non-inverted output terminal QT. Accordingly, the time tr during which the inverted output terminal QB is transitioned from the low level to the high one becomes longer as compared with the time tf during which the non-inverted output terminal QT is transitioned from the high level to the low one. For basically the same reason, the time td (rise) during which the non-inverted output terminal QT is transitioned from the low level to the high one becomes longer as compared with the time td (fall) during which the inverted output terminal QB has been transitioned from the high level to the low one. As a consequence, a timing with which one of output signals (i.e., QB output signal and QT output signal) at a complementary level in the RS flip-flop circuit 9 cuts across a logical threshold-value when the one of the output signals is transitioned from the high level to the low one differs from a timing with which the other of the output signals at the complementary level cuts across the logical threshold-value when the other is transitioned from the low level to the high one. As a result, in a (not-illustrated) circuit located at the subsequent stage of the RS flip-flop circuit 9, it becomes necessary to take up an enlarged timing margin for taking in the input signals. On account of this, a certain amount of time becomes required for signal transmission from the RS flip-flop circuit 9 to the subsequent-stage circuit.

In contrast thereto, the RS flip-flop circuit 12 illustrated in FIG. 1 includes the p-channel MOS transistors MP3 and MP4 and the inverters INV3 and INV4. This condition reduces the differences between the rising times and the falling times of the output signals in the following manner:

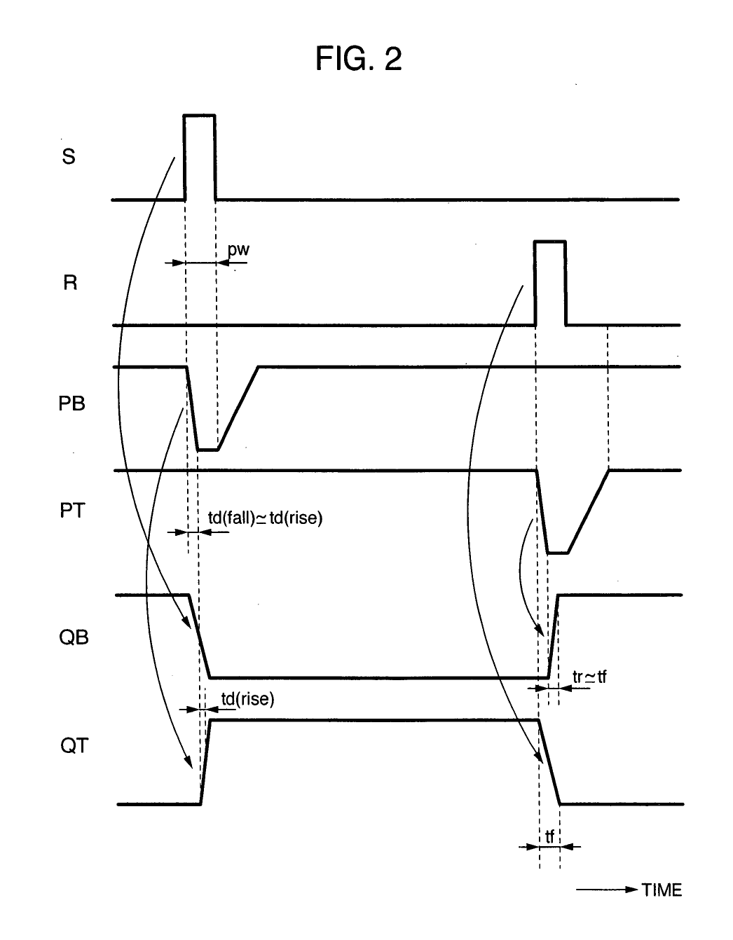

FIG. 2 illustrates an operation timing for the main part in the RS flip-flop circuit 12 illustrated in FIG. 1.

If the set-signal input terminal S is turned into the high level, the n-channel MOS transistor MN3 is turned on, so that the inverted output terminal QB is turned into the low level. Simultaneously with this, when an output node PB of the inverter INV3 is transitioned from a high level to a low one, a gate electrode of the p-channel MOS transistor MP4 is turned into a low level, and thus the p-channel MOS transistor MP4 is turned on. This quickly raises the non-inverted output terminal QT up to the high level. In this way, the non-inverted output terminal QT is quickly raised up to the high level. This condition makes the falling time td (fall) of the inverted output terminal QB and the rising time td (rise) of the non-inverted output terminal QT substantially equal to each other.

Meanwhile, if the reset-signal input terminal R is turn into the high level, the n-channel MOS transistor MN4 is turned on. This lowers the non-inverted output terminal QT to the low level. Simultaneously with this, an output node PT of the inverter INV4 is transitioned from a high level to a low one. As a result, a gate electrode of the p-channel MOS transistor MP3 is transitioned to a low level, and thus the p-channel MOS transistor MP3 is turned on. This quickly raises the inverted output terminal QB up to the high level. In this way, the inverted output terminal QB is quickly raised up to the high level. This condition makes the rising time tr of the inverted output terminal QB and the falling time tf of the non-inverted output terminal QT substantially equal to each other.

The above-described embodiment makes it possible to acquire the following advantage and effect:

The falling time td (fall) of the inverted output terminal QB and the rising time td (rise) of the non-inverted output terminal QT are made substantially equal to each other. Also, the rising time tr of the inverted output terminal QB and the falling time tf of the non-inverted output terminal QT are made substantially equal to each other. This condition reduces the differences between the rising times and the falling times of the output signals. Accordingly, a timing with which one of the output signals at a complementary level in the RS flip-flop circuit 12 cuts across a logical threshold-value when the one of the output signals has been transitioned from the high level to the low one becomes substantially equal to a timing with which the other of the output signals at the complementary level cuts across the logical threshold-value when the other has been transitioned from the low level to the high one. As a result, in the subsequent-stage circuit 13 located at the subsequent stage of the RS flip-flop circuit 12, it becomes possible to reduce the timing margin for taking in the input signals. Consequently, by the amount equivalent thereto, it becomes possible to shorten the signal-transmission time from the RS flip-flop circuit 12 to the subsequent-stage circuit 13.

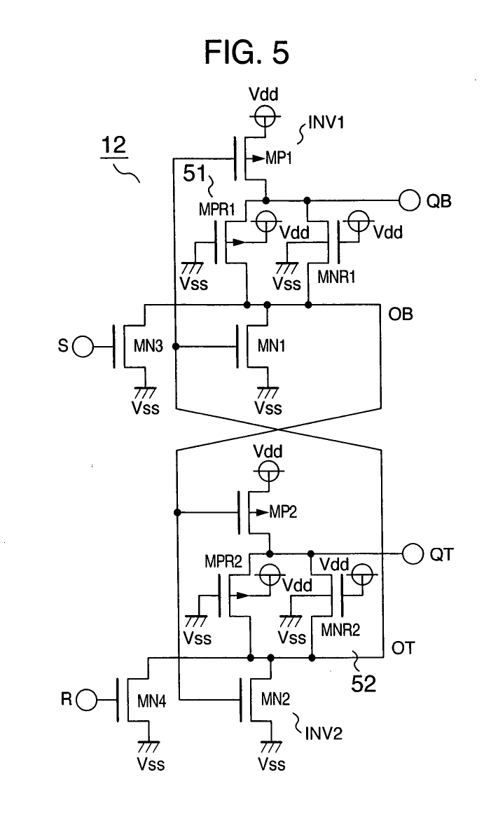

FIG. 5 illustrates another configuration embodiment of the RS flip-flop circuit 12.

A first resistor part 51 is provided between the p-channel MOS transistor MP1 and the n-channel MOS transistor MN1, and the inverted output terminal QB is drawn out of a connection node between the p-channel MOS transistor MP1 and the first resistor part 51. Moreover, a second resistor part 52 is provided between the p-channel MOS transistor MP2 and the n-channel MOS transistor MN2, and the non-inverted output terminal QT is drawn out of a connection node between the p-channel MOS transistor MP2 and the second resistor part 52. The first resistor part 51 is formed by connecting in parallel a p-channel MOS transistor MPR1 and an n-channel MOS transistor MNR1. The second resistor part 52 is formed by connecting in parallel a p-channel MOS transistor MPR2 and an n-channel MOS transistor MNR2. Gate electrodes of the p-channel MOS transistors MPR1 and MPR2 and back gate electrodes of the n-channel MOS transistors MNR1 and MNR2 are connected to low potential power-supplies Vss. Back gate electrodes of the p-channel MOS transistors MPR1 and MPR2 and gate electrodes of the n-channel MOS transistors MNR1 and MNR2 are connected to high potential power-supplies Vdd. This allows the p-channel MOS transistors MPR1 and MPR2 and the n-channel MOS transistors MNR1 and MNR2 to be always maintained in ON states, thereby making it possible to acquire predetermined ON resistance values corresponding to gate size of the MOS transistors.

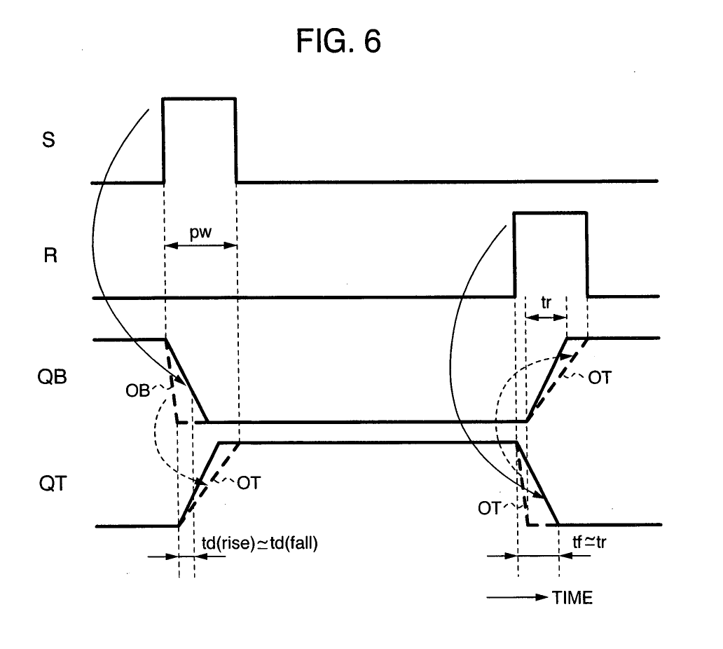

FIG. 6 illustrates an operation timing for the main part in the RS flip-flop circuit illustrated in FIG. 5.

If the set-signal input terminal S is driven to a high level, the n-channel MOS transistor MN3 is turned on. This performs an electric-charge extraction from an in-series connection node (which is referred to as “node OB”) between the first resistor part 51 and the n-channel MOS transistor MN1. With the intervention of the first resistor part 51, this electric-charge extraction is completed in a shorter time as compared with the case where there exists none of the first resistor part 51 (refer to FIG. 3). Moreover, if the node OB is driven to a low level by this pull out of charge extraction, the p-channel MOS transistor MP2 is turned on. This drives the non-inverted output terminal QT to a high level. Also, when the node OB is turn into the low level, an electric-charge extraction therefrom is performed via the first resistor part 51. This drives the inverted output terminal QB to a low level. In the circuit configuration illustrated in FIG. 5, ON resistance values of the MOS transistors MPR1 and MNR1 in the first resistor part 51 are set so that the falling time td (fall) at the inverted output terminal QB and the rising time td (rise) at the non-inverted output terminal QT will become equal to each other.

Also, if the reset-signal input terminal R is turn into a high level, the n-channel MOS transistor MN4 is turned on. This performs a pull out of charge from an in-series connection node (which is referred to as “node OT”) between the second resistor part 52 and the n-channel MOS transistor MN2. With the intervention of the second resistor part 52, this pull out of charge is completed in a shorter time as compared with the case where there exists none of the second resistor part 52 (refer to FIG. 3). Moreover, if the node OT is turn into a low level by this pull out of charge, the p-channel MOS transistor MP1 is turned on. This drives the inverted output terminal QB to a high level. Also, when the node OT is turn into the low level, a pull out of charge is performed via the second resistor part 52. This drives the non-inverted output terminal QT to a low level. In the circuit configuration illustrated in FIG. 5, ON resistance values of the MOS transistors MPR2 and MNR2 in the second resistor part 52 are set so that the falling time tf at the non-inverted output terminal QT and the rising time tr at the inverted output terminal QB will become equal to each other.

In this way, in the case as well where the first resistor part 51 and the second resistor part 52 are provided, the falling time td (fall) of the inverted output terminal QB and the rising time td (rise) of the non-inverted output terminal QT are made substantially equal to each other. Also, the rising time tr of the inverted output terminal QB and the falling time tf of the non-inverted output terminal QT are made substantially equal to each other. This condition reduces the differences between the rising times and the falling times of the output signals. Accordingly, a timing with which one of the output signals at a complementary level in the RS flip-flop circuit 12 cuts across a logical threshold-value when the one of the output signals is transitioned from the high level to the low one becomes substantially equal to a timing with which the other of the output signals at the complementary level cuts across the logical threshold-value when the other has been transitioned from the low level to the high one. As a result, in the subsequent-stage circuit 13 located at the subsequent stage of the RS flip-flop circuit 12, it becomes possible to reduce the timing margin for taking in the input signals. Consequently, by the amount equivalent thereto, it becomes possible to shorten the signal-transmission time from the RS flip-flop circuit 12 to the subsequent-stage circuit 13.

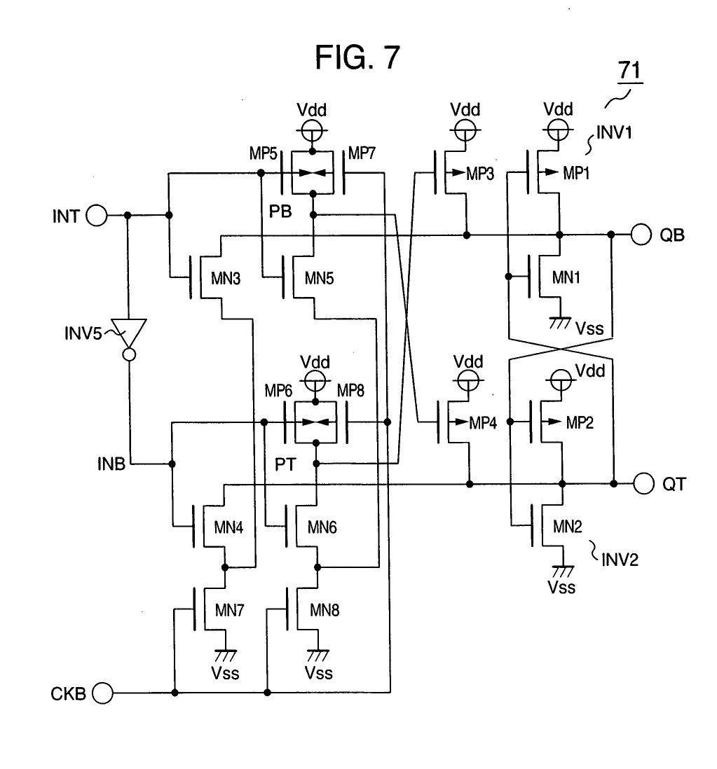

Instead of the RS flip-flop circuit 12 illustrated in FIG. 1, it is possible to employ a latch circuit 71 illustrated in FIG. 7. In FIG. 7, the same reference notations are allocated to configuration components which possess the same functions as the ones illustrated in FIG. 1. In the latch circuit 71 illustrated in FIG. 7, there are provided a data input terminal INT for taking in data, and a clock-signal input terminal CKB for taking in a clock signal. The data taken in via the data input terminal INT is transmitted to a p-channel MOS transistor MP5 and n-channel MOS transistors MN5 and MN3. A p-channel MOS transistor MP7 is connected to the p-channel MOS transistor MP5 in parallel. The n-channel MOS transistor MN5 is connected to the p-channel MOS transistors MP5 and MP7 in series. A p-channel MOS transistor MP4 is driven by an output signal from this in-series connection node PB. A source electrode of the n-channel MOS transistor MN5 is connected to a low potential power-supply Vss via an n-channel MOS transistor MN8. There is provided an inverter INV5 for inverting the logical value of the data inputted via the data input terminal INT. An output signal INB from this inverter INV5 is transmitted to a p-channel MOS transistor MP6 and n-channel MOS transistors MN6 and MN4. A p-channel MOS transistor MP8 is connected to the p-channel MOS transistor MP6 in parallel. The n-channel MOS transistor MN6 is connected to the p-channel MOS transistors MP6 and MP8 in series. A source electrode of the n-channel MOS transistor MN6 is connected to a low potential power-supply Vss via the n-channel MOS transistor MN8. Source electrodes of the n-channel MOS transistors MN3 and MN4 are connected to a low potential power-supply Vss via an n-channel MOS transistor MN7. The clock signal taken in via the clock-signal input terminal CKB is transmitted to the n-channel MOS transistors MN7 and MN8 and the p-channel MOS transistors MP7 and MP8.

According to the above-described configuration, the NAND logical-operation value of the data taken in via the data input terminal INT and the clock signal inputted via the clock-signal input terminal CKB is acquired from the node PB. The p-channel MOS transistor MP4 is driven based on the output signal from this node PB. Also, the NAND logical-operation value of the output signal INB from the inverter INV5 and the above-described clock signal is acquired from a node PT. The p-channel MOS transistor MP3 is driven based on the output signal from this node PT. The p-channel MOS transistor MP3 drives the inverted output terminal QB to a high level, and the p-channel MOS transistor MP4 drives the non-inverted output terminal QT to a high level. As a result, similarly to the case illustrated in FIG. 1, the falling time td(fall) of the inverted output terminal QB and the rising time td(rise) of the non-inverted output terminal QT are made substantially equal to each other. Also, the rising time tr of the inverted output terminal QB and the falling time tf of the non-inverted output terminal QT are made substantially equal to each other. This condition reduces the differences between the rising times and the falling times of the output signals.

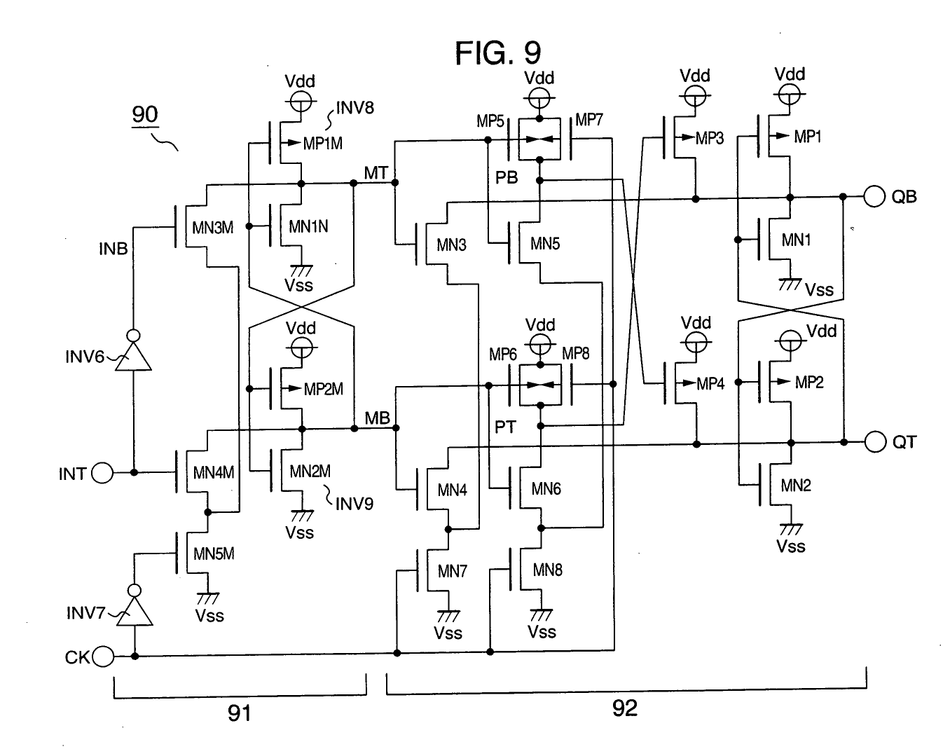

The present invention is also applicable to the case where a master-slave latch circuit illustrated in FIG. 9 is included. The master-slave latch circuit 90 includes a master latch circuit 91 and a slave latch circuit 92 connected thereto. This slave latch circuit 92 is equivalent to a circuit resulting from omitting the inverter INV5 in the latch circuit 71 illustrated in FIG. 7. The master latch circuit 91 is configured as follows:

There are provided an inverter INV6 for inverting data taken in via a data input terminal INT, and an inverter INV7 for inverting a clock signal taken in via a clock-signal input terminal CK. A p-channel MOS transistor MP1M and an n-channel MOS transistor MN1M are connected to each other in series, which forms an inverter INV8. A p-channel MOS transistor MP2M and an n-channel MOS transistor MN2M are connected to each other in series, which forms an inverter INV9. The inverter INV8 and the inverter INV9 are cross-connected to each other. An n-channel MOS transistor MN3M is connected to the n-channel MOS transistor MN1M in parallel. This n-channel MOS transistor MN3M is driven by an output signal INB from the inverter INV6. An n-channel MOS transistor MN4M is connected to the n-channel MOS transistor MN2M in parallel. This n-channel MOS transistor MN4M is driven by the data taken in via the data input terminal INT. Source electrodes of the n-channel MOS transistors MN3M and MN4M are connected to a low potential power supply Vss via an n-channel MOS transistor MN5M.

In the above-described configuration, the data inputted from the data input terminal INT is taken into the master latch circuit 91 in synchronization with the clock signal inputted from the clock-signal input terminal CK. The data held in the master latch circuit 91 is transmitted to the slave latch circuit 92 in synchronization with a clock signal next thereto. In the master-slave latch circuit 90 like this as well, similarly to the case of the latch circuit 71 illustrated in FIG. 7, the p-channel MOS transistors MP3 and MP4 are provided in the slave latch circuit 92. As a result, the falling time td(fall) of the inverted output terminal QB and the rising time td(rise) of the non-inverted output terminal QT are made substantially equal to each other. Also, the rising time tr of the inverted output terminal QB and the falling time tf of the non-inverted output terminal QT are made substantially equal to each other. This condition reduces the differences between the rising times and the falling times of the output signals.

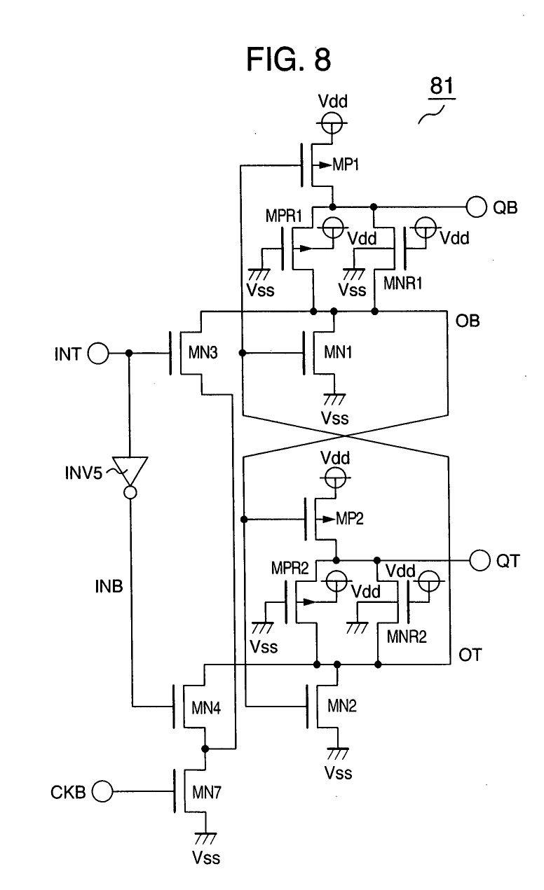

FIG. 8 illustrates another configuration embodiment of the above-described latch circuit. A latch circuit 81 illustrated in FIG. 8 results from adding the inverter INV5 and an n-channel MOS transistor MN7 to the RS flip-flop circuit 12 illustrated in FIG. 5. This addition allows the latch circuit 81 to be operated in synchronization with clock signals. In the configuration like this as well, it is possible to acquire basically the same advantage and effect as the one illustrated in FIG. 5.

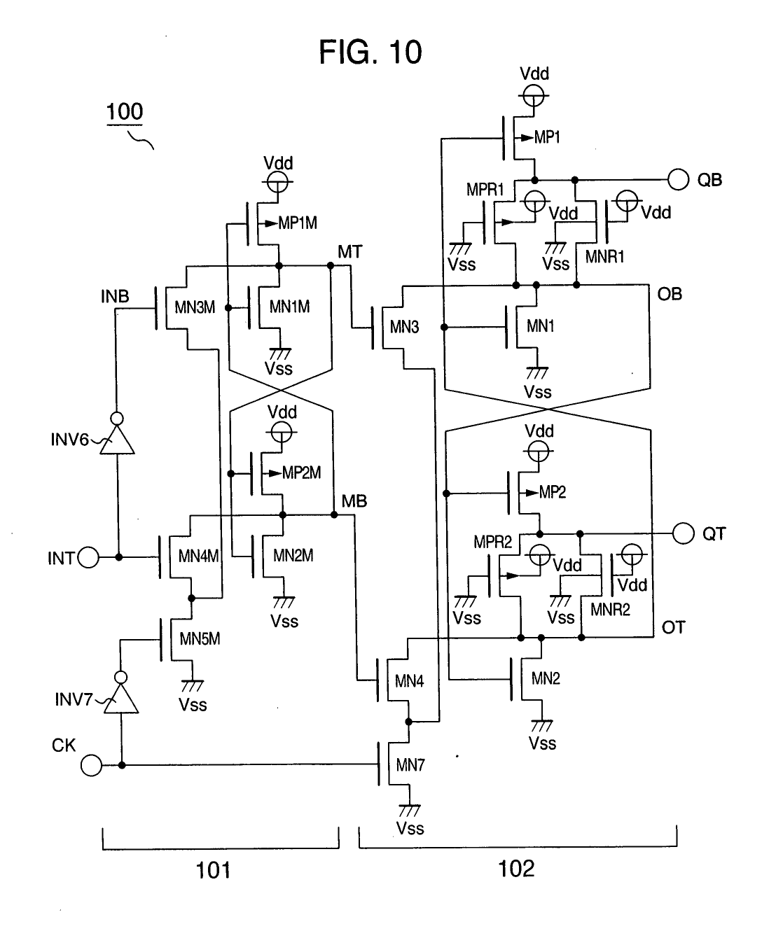

FIG. 10 illustrates another configuration embodiment of the above-described master-slave latch circuit. A master-slave latch circuit 100 illustrated in FIG. 10 is formed by a connection of a master latch circuit 101 and a slave latch circuit 102. The configuration of the master latch circuit 101 is defined as the same as the one of the master latch circuit 91 illustrated in FIG. 9. Also, the configuration of the slave latch circuit 102 is defined as the same as a configuration resulting from omitting the inverter INV5 in the latch circuit 81 illustrated in FIG. 8.

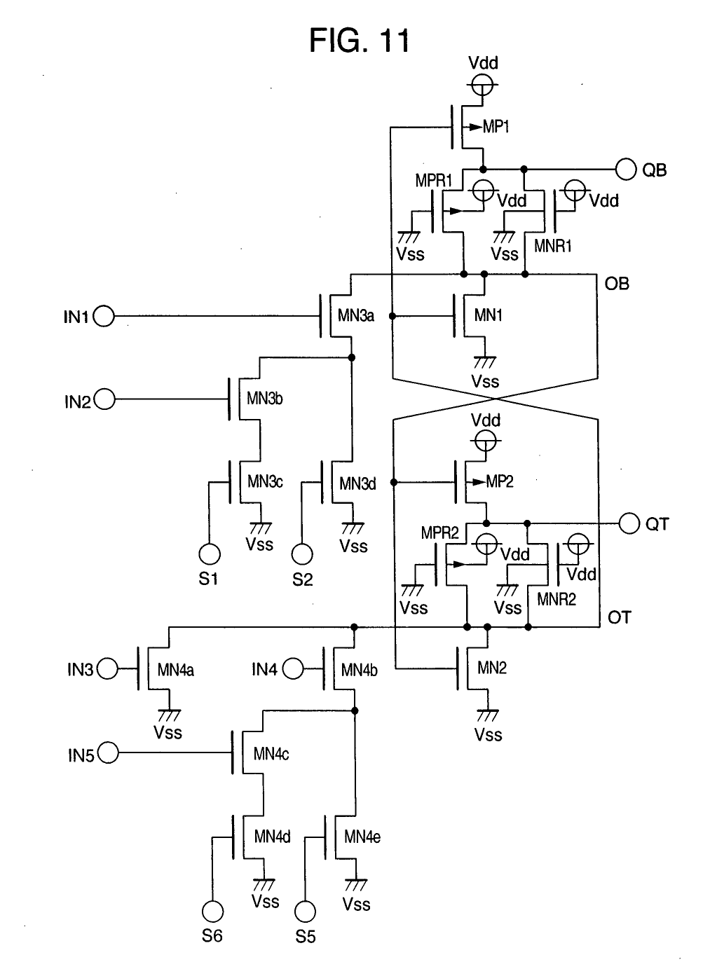

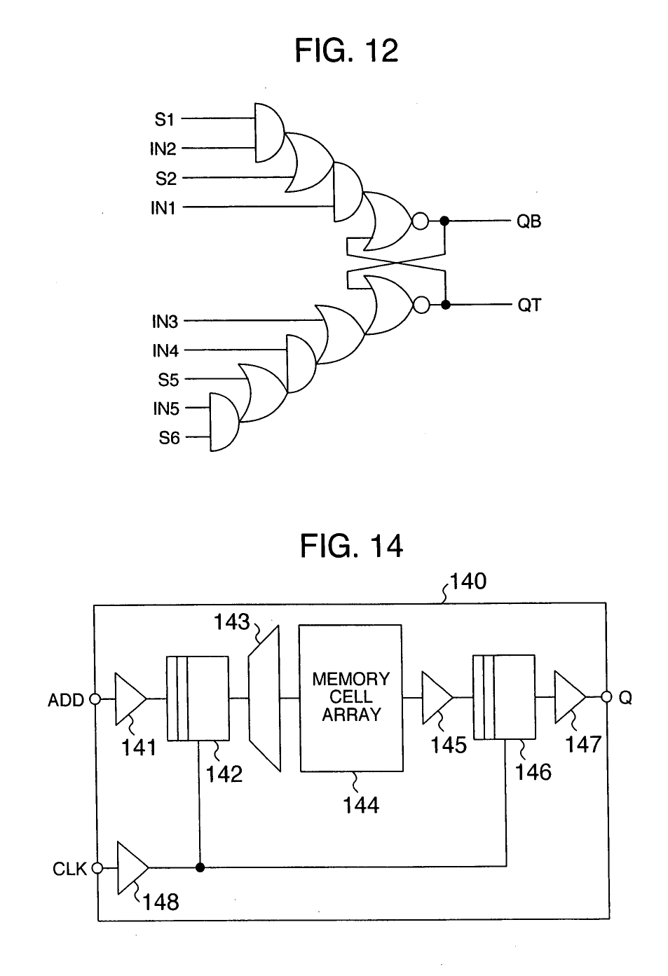

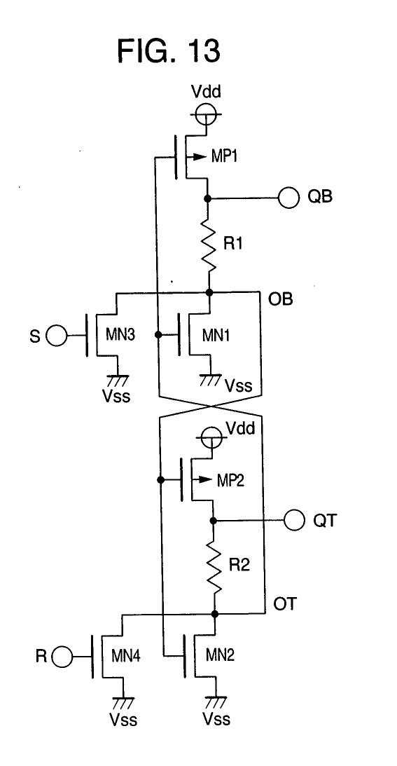

On the input side of the RS flip-flop circuit illustrated in FIG. 5, it is possible to set up a variety of input logical circuit components. FIG. 11 illustrates a configuration embodiment in that case. Namely, n-channel MOS transistors MN3a to MN3d are set up in substitution for the n-channel MOS transistor MN3 in FIG. 5, and n-channel MOS transistors MN4a to MN4e are set up in substitution for the n-channel MOS transistor MN4 in FIG. 5. FIG. 12 represents the circuit illustrated in FIG. 11, using the corresponding logical symbols. Reference numerals IN1 to IN5 denote data input terminals, and S1 to S6 denote selection signals for selecting combinations of the data input terminals IN1 to IN5.

Next, the explanation will be given below concerning an application embodiment of the master-slave latch circuit illustrated in FIG. 9 or FIG. 10.

FIG. 14 illustrates a synchronization-type SRAM (: Static Random Access Memory). The synchronization-type memory 140 illustrated in FIG. 14, although not specifically limited, includes an input buffer 141, an input register 142, a decoder 143, a memory-cell array 144, a reading amplifier 145, an output buffer 147, and a clock buffer 148.

The memory-cell array 144 includes plural word lines, plural bit lines arranged such that the bit lines intersect the word lines, and static-type memory cells (which are simply referred to as “memory cells”) set to the intersection points between the word lines and the bit lines. An address signal inputted via an address input terminal Add is taken into the input buffer 141, then being transmitted to the input register 142 via this input buffer 141. A clock signal inputted via a clock-signal input terminal CLK is transmitted to the input register 142 and an output register 146 via the clock buffer 148. The input register 142 holds the output data from the input buffer 141 in synchronization with the clock signal transmitted via the clock buffer 148. This held data is transmitted to the decoder 143 located at the subsequent stage. The decoder 143 decodes the output data from the input register 142, thereby generating a signal for selectively driving a single word line from among the plural word lines in the memory-cell array 144. The reading amplifier 145 amplifies the data read out from the memory-cell array 144, then transmitting the amplified data to the output register 146 located at the subsequent stage. The output register 146 holds the output data from the reading amplifier 145 in synchronization with the clock signal transmitted via the clock buffer 148. This held data is outputted from an output terminal Q via the output buffer 147 located at the subsequent stage.

The master-slave latch circuit illustrated in FIG. 9 or FIG. 10 is applicable as the input register 142 or the output register 146. In the master-slave latch circuit illustrated in FIG. 9 or FIG. 10, the falling time td (fall) of the inverted output terminal QB and the rising time td (rise) of the non-inverted output terminal QT are made substantially equal to each other. Also, the rising time tr of the inverted output terminal QB and the falling time tf of the non-inverted output terminal QT are made substantially equal to each other. This condition reduces the differences between the rising times and the falling times of the output signals. As a consequence, in the decoder 143 and the output buffer 147, it becomes possible to reduce a timing margin for taking in the input signal. Accordingly, by the amount equivalent thereto, it becomes possible to shorten the signal-transmission time. This makes it advantageous to accomplish the implementation of high-speed operation of the synchronization-type SRAM.

So far, the concrete explanation has been given concerning the invention devised by the present inventor. It is needless to say, however, that the present invention is not limited thereto, but is modifiable in a variety of ways within the scope not departing from its essence and spirit.

Although, in the configuration embodiments illustrated in, e.g., FIG. 5, FIG. 8, and FIG. 10, the first resistor part 51 and the second resistor part 52 have been configured using the MOS transistors it is also allowable to employ resistor elements R1 and R2 as are illustrated in FIG.

The resistor elements R1 and R2, although not specifically limited, can be formed using a polysilicon layer, a diffusion layer, or the like.

In the explanation so far, the explanation has been given mainly concerning the case where the invention devised by the present inventor is applied to the SRAM, i.e., the utilization field which has become background of the invention. The present invention, however, is not limited thereto, but is widely applicable to the various types of semiconductor integrated circuits.

The present invention is applicable on the condition that the first circuit and the second circuit which is cross-connected thereto are included.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor integrated circuit comprising:
a first circuit formed by connection of a first-conductivity-type first transistor and a second-conductivity-type second transistor whose conductivity type differs from that of said first transistor;
a second circuit formed by connection of a first-conductivity-type third transistor and a second-conductivity-type fourth transistor, input/output of said second circuit being cross-connected to output/input of said first circuit;
first resistor means provided between said first transistor and said second transistor; and
second resistor means provided between said third transistor and said fourth transistor.

2. A semiconductor integrated circuit including a latch circuit capable of latching input data in synchronization with a clock signal, said latch circuit comprising:
a first circuit formed by connection of a first-conductivity-type first transistor and a second-conductivity-type second transistor whose conductivity type differs from that of said first transistor;
a second circuit formed by connection of a first-conductivity-type third transistor and a second-conductivity-type fourth transistor, input/output of said second circuit being cross-connected to output/input of said first circuit;
a second-conductivity-type fifth transistor capable of driving an output node of said first circuit to a low level in response to a first input signal;
a second-conductivity-type sixth transistor capable of driving an output node of said second circuit to a low level in response to a second input signal;
first resistor means provided between said first transistor and said second transistor, an inverted output terminal being drawn out of a connection node between said first transistor and said first resistor means; and
second resistor means provided between said third transistor and said fourth transistor, a non-inverted output terminal being drawn out of a connection node between said third transistor and said second resistor means.

3. A semiconductor integrated circuit including a master-slave-type flip-flop circuit which includes a master latch circuit and a slave latch circuit connected thereto, held data in said master latch circuit being transmitted to said slave latch circuit in synchronization with a clock signal inputted, said slave latch circuit comprising:
a first circuit formed by connection of a first-conductivity-type first transistor and a second-conductivity-type second transistor whose conductivity type differs from that of said first transistor;
a second circuit formed by connection of a first-conductivity-type third transistor and a second-conductivity-type fourth transistor, input/output of said second circuit being cross-connected to output/input of said first circuit;
a second-conductivity-type fifth transistor capable of driving an output node of said first circuit to a low level in response to a first input signal;
a second-conductivity-type sixth transistor capable of driving an output node of said second circuit to a low level in response to a second input signal;
first resistor means provided between said first transistor and said second transistor, an inverted output terminal being drawn out of a connection node between said first transistor and said first resistor means; and
second resistor means provided between said third transistor and said fourth transistor, a non-inverted output terminal being drawn out of a connection node between said third transistor and said second resistor means.

4. The semiconductor integrated circuit according to claim 1, wherein each of said first resistor means and said second resistor means is formed using MOS transistors.

5. The semiconductor integrated circuit according to claim 1, wherein each of said first resistor means and said second resistor means is formed using resistor elements.
